(19) United States
(12) Patent Application Publication
(10) Pub. No.: US 2024/0258157 A1
(43) Pub. Date: Aug. 1, 2024

(54) WIRING STRUCTURE AND SEMICONDUCTOR DEVICE COMPRISING THE SAME

(71) Applicant: SAMSUNG ELECTRONICS CO., LTD., SUWON-SI (KR)

(72) Inventors: Jinyong LEE, Suwon-si (KR); Yungi CHOI, Suwon-si (KR); Jihye KIM, Suwon-si (KR); Taewon KIM, Suwon-si (KR); Yun PARK, Suwon-si (KR); Jaeyoung SEO, Suwon-si (KR); Gyeore LEE, Suwon-si (KR); Heesu EOM, Suwon-si (KR)

(21) Appl. No.: 18/411,164

(22) Filed: Jan. 12, 2024

(30) Foreign Application Priority Data
Jan. 27, 2023 (KR) 10-2023-0011107

(51) Int. Cl. H01L 21/768; H01L 23/522

(52) U.S. Cl. CPC H01L 21/76814; H01L 21/76816; H01L 23/5226

(57) ABSTRACT

A wiring structure includes an etch stop film disposed on a substrate. A first insulating film is disposed on the etch stop film. A first wiring layer extends in a vertical direction perpendicular to an upper surface of the substrate and extends through the first insulating film and the etch stop film. A sidewall of the first wiring layer forms a first inclination angle of about 88 degrees to about 90 degrees with respect to a first horizontal direction parallel to the upper surface of the substrate. A surface of the first insulating film and a surface of the etch stop film in direct contact with the first wiring layer have a carbon (C) concentration less than or equal to about 3 at %.

### CROSS-REFERENCE TO RELATED APPLICATION

This application claims priority under 35 U.S.C. § 119 to Korean Patent Application No. 10-2023-0011107, filed on Jan. 27, 2023 in the Korean Intellectual Property Office, the disclosure of which is incorporated by reference in its entirety herein.

### 1. TECHNICAL FIELD

The present inventive concept relates to a wiring structure and a semiconductor device including the wiring structure. More specifically, the present inventive concept relates to a back end of line (BEOL) wiring structure and a semiconductor device including the same.

### 2. DISCUSSION OF RELATED ART

With the advancement of the electronics industry, there has been an increased interest and consumer demand concerning semiconductor devices that are miniaturized and highly integrated. In accordance with this trend, the size of a wiring structure included in a semiconductor device is also decreasing. As the size of the wiring structure decreases, when forming the wiring structure, a wiring structure having a tapered profile is formed. When the wiring structure has a tapered profile, the wiring structure and the lower contact structure located under the wiring structure are mis-aligned with each other. Therefore, the functional characteristics of a semiconductor device including the lower contact structure may deteriorate.

### SUMMARY

Embodiments of the present inventive concept provides a wiring structure with increased functional characteristics and functional reliability and a semiconductor device including the same.

According to an embodiment of the present inventive concept, a wiring structure includes an etch stop film disposed on a substrate. A first insulating film is disposed on the etch stop film. A first wiring layer extends in a vertical direction perpendicular to an upper surface of the substrate and extends through the first insulating film and the etch stop film. A sidewall of the first wiring layer forms a first inclination angle of about 88 degrees to about 90 degrees with respect to a first horizontal direction parallel to the upper surface of the substrate. A surface of the first insulating film and a surface of the etch stop film in direct contact with the first wiring layer have a carbon (C) concentration less than or equal to about 3 at %.

According to an embodiment of the present inventive concept, a semiconductor device includes a substrate. A front end of line (FEOL) layer includes a plurality of lower contact structures including a first lower contact structure and a second lower contact structure, and an interlayer insulating film covering the plurality of lower contact structures. A wiring structure is disposed on the FEOL layer. The wiring structure comprises an etch stop film disposed on the substrate, a first insulating film disposed on the etch stop film, and a first wiring layer extending in a vertical direction perpendicular to an upper surface of the substrate and extending through the first insulating film and the etch stop film. A sidewall of the first wiring layer forms a first inclination angle of about 88 degrees to about 90 degrees with respect to a first horizontal direction parallel to an upper surface of the substrate and a surface of the first insulating film and a surface of the etch stop film in direct contact with the first wiring layer have a carbon (C) concentration of about 3 at % or less.

According to an embodiment of the present inventive concept, a wiring structure includes an etch stop film disposed on a substrate and including oxide-doped carbide (ODC). A first insulating film is disposed on the etch stop film. A first wiring layer extends in a vertical direction perpendicular to an upper surface of the substrate and extending through the first insulating film and the etch stop film. A second wiring layer is spaced apart from the first wiring layer and extends in the vertical direction through the first insulating film and the etch stop film. A sidewall of the first wiring layer forms a first inclination angle in a range of about 88 degrees to about 90 degrees with respect to a first horizontal direction parallel to a top surface of the substrate. A sidewall of the second wiring layer forms a second inclination angle in a range of about 83 degrees to about 87 degrees with respect to the first horizontal direction. A surface of the first insulating film in direct contact with the first wiring layer, a surface of the etch stop film and a surface of the first insulating film in direct contact with the second wiring layer, and a surface of the etch stop film have a carbon (C) concentration less than or equal to about 3 at %.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor device according to an embodiment of the present inventive concept:

FIG. 2A is an enlarged cross-sectional view of an area EX1 of FIG. 1 according to an embodiment of the present inventive concept;

FIG. 2B is an enlarged cross-sectional view of an area EX2 of FIG. 1 according to an embodiment of the present inventive concept;

FIG. 3 is a flowchart illustrating a manufacturing process of a wiring structure according to an embodiment of the present inventive concept; and

FIGS. 4A to 4I are cross-sectional views showing each step of a manufacturing process of a wiring structure according to embodiments of the present inventive concept.

### DETAILED DESCRIPTION OF EMBODIMENTS

Hereinafter, embodiments of the present inventive concept will be described in detail with reference to the accompanying drawings. The same reference numerals are used for the same components in the drawings, and duplicate descriptions thereof may be omitted for economy of description. Unless otherwise specifically defined below, atomic (at) % refers to the number of atoms occupied by the corresponding component expressed as a percentage of the total number of atoms.

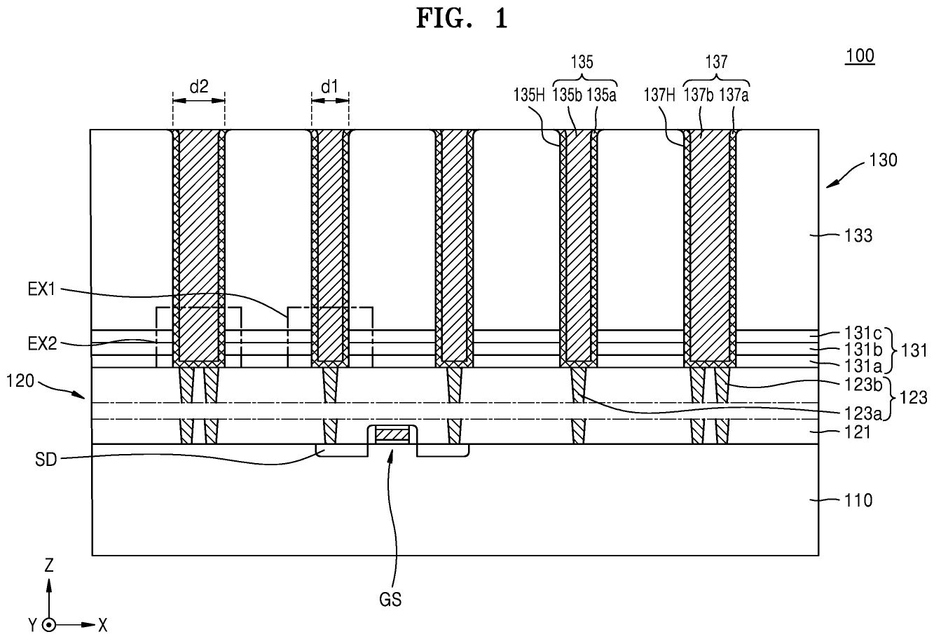

FIG. 1 is a cross-sectional view showing a semiconductor device 100 according to an embodiment.

Referring to FIG. 1, the semiconductor device 100 may include a substrate 110, a front end of line (FEOL) layer 120 disposed on the substrate 110, and a wiring structure 130 disposed on the FEOL layer 120 (e.g., in the Z direction).

In an embodiment, the semiconductor device 100 may be included in, for example, volatile memory or non-volatile memory. The volatile memory may include, for example, dynamic random-access memory (DRAM) and static RAM (SRAM), and the non-volatile memory may include, for example, read-only memory (ROM), phase-change RAM (PRAM), magnetoresistive RAM (MRAM), resistive RAM (ReRAM), ferroelectric RAM (FeRAM), and flash memory. However, embodiments of the present inventive concept are not necessarily limited thereto.

The substrate 110 may include silicon, for example, single crystal silicon, polycrystalline silicon, or amorphous silicon. For example, in an embodiment the substrate 110 may include at least one compound selected from the group consisting of Ge, SiGe, SiC, GaAs, InAs, and InP. In some embodiments, the substrate 110 may include a conductive region, for example, a well doped with an impurity, or a structure doped with an impurity.

The substrate 110 may include an active surface and an inactive surface opposite to the active surface. In an embodiment, the active surface may correspond to the upper surface of the substrate 110 and the inactive surface may correspond to the lower surface of the substrate 110. A gate structure GS may be disposed on the active surface of the substrate 110. In an embodiment, the gate structure GS may include a gate spacer, a gate insulating film, a gate electrode, and a gate capping film. A source/drain region SD may be disposed on a portion of the active surface of the substrate 110. The source/drain region SD may be a region doped with impurities on the active surface of the substrate 110. The impurity may be, for example, an n-type impurity or a p-type impurity. The gate structure GS and the source/drain region SD may together function as one transistor. Although the gate structure GS and the source/drain region S/D are shown as one in FIG. 1, embodiments of the present inventive concept are not necessarily limited thereto.

An interlayer insulating film 121 may be disposed on the substrate 110 (e.g., disposed directly thereon in the Z direction). The interlayer insulating film 121 may be made of an insulating material. In an embodiment, the insulating material may include, for example, silicon oxide, silicon nitride, silicon oxynitride, or a combination thereof.

A plurality of lower contact structures 123 may be disposed within the interlayer insulating film 121. Each of the plurality of lower contact structures 123 may pass through at least a portion of the interlayer insulating film 121 and extend in a vertical direction (e.g., the Z direction) perpendicular to the upper surface of the substrate 110. Each of the plurality of lower contact structures 123 may be made of a metal material. The metal material may include, for example, at least one compound selected from tungsten (W), copper (Cu), aluminum (Al), nickel (Ni), cobalt (Co), molybdenum (Mo), and an alloy thereof. In an embodiment, the lower contact structure 123 may include a first lower contact structure 123a and a second lower contact structure 123b.

In an embodiment, the lower surfaces of the plurality of first lower contact structures 123a may be connected to a voltage source or a ground source on the active surface of the substrate 110, and the upper surfaces of the plurality of first lower contact structures 123a may be connected to a first wiring layer 135. Although FIG. 1 illustrates that one first lower contact structure 123a is connected to one first wiring layer 135, embodiments of the present inventive concept are not necessarily limited thereto. For example, in some embodiments two or more first lower contact structures 123a may be connected to one first wiring layer 135. The lower surface of each of the plurality of first lower contact structures 123a may be connected to (e.g., directly connected thereto) a source/drain region SD disposed on a portion of the active surface of the substrate 110.

The lower surface of each of the plurality of second lower contact structures 123b may be connected to (e.g., directly connected thereto) a portion of the active surface of the substrate 110, and the upper surface of each of the plurality of second lower contact structures 123b may be connected to (e.g., directly connected thereto) the second wiring layer 137. Although FIG. 1 illustrates that two second lower contact structures 123b is connected to one second wiring layer 137, embodiments of the present inventive concept are not necessarily limited thereto. For example, in an embodiment one or three or more second lower contact structures 123b may be connected to one second wiring layer 137.

The source/drain region SD, the gate structure GS, interlayer insulating film 121, and the plurality of lower contact structures 123 described above may together constitute the FEOL layer 120. In an embodiment, the FEOL layer 120, for example, may constitute a logic cell including a fin field effect transistor (FinFET), a multi-bridge channel field effect transistor (MBCFET), a gate all around field effect transistor (GAAFET), a metal-oxide-semiconductor field effect transistor (MOSFET), a system large scale integration (LSI), a micro-electro-mechanical system (MEMS), an active element, or a passive element.

The wiring structure 130 may be disposed on the FEOL layer 120 (e.g., in the Z direction). The wiring structure 130 may also be referred to as a BEOL layer. The wiring structure 130 may include an etch stop film 131, a first insulating film 133, a first wiring layer 135, and a second wiring layer 137.

The etch stop film 131 may be disposed on the interlayer insulating film 121 between layers. The etch stop film 131 may include a plurality of layers. For example, in an embodiment the etch stop film 131 may include a first etch stop film 131a, a second etch stop film 131b, and a third etch stop film 131c sequentially stacked on the interlayer insulating film 121 (e.g., in the Z direction). In an embodiment, the first etch stop film 131a, the second etch stop film 131b, and the third etch stop film 131c may be made of different materials from each other. However, embodiments of the present inventive concept are not necessarily limited thereto. For example, in an embodiment, the first etch stop film 131a and the third etch stop film 131c may be made of the same material as each other, and the second etch stop film 131b may be made of a material different from that of the first etch stop film 131a and the third etch stop film 131c. For example, in an embodiment the first etch stop film 131a and the third etch stop film 131c may be made of an insulating material including oxygen. The oxygen-containing insulating material may be, for example, aluminum oxide. For example, in an embodiment the second etch stop film 131b may be made of an insulating material including carbon. The insulating material including carbon may be, for example, oxide-doped carbon (ODC). However, embodiments of the present inventive concept are not necessarily limited thereto.

The first insulating film 133 may be disposed on the etch stop film 131 (e.g., disposed directly thereon in the Z direction). In an embodiment, the first insulating film 133 may be made of a low-k material. For example, in an embodiment the low-k material may include Torene SilaZene (TOSZ), Undoped Silica Glass (USG), Borosilica Glass (BSG), PhosphoSilica Glass (PSG), BoroPhosphoSilica Glass (BPSG), Plasma Enhanced Tetra Ethyl Ortho Silicate (PETEOS), Fluoride Silicate Glass (FSG), Carbon Doped Silicon Oxide (CDO), Amorphous Fluorinated Carbon, Organo Silicate Glass (OSG), or a combination thereof. However, embodiments of the present inventive concept are not necessarily limited thereto. In an embodiment, the first insulating film 133 may have a sidewall having a rounded top. A sidewall having a rounded upper portion of the first insulating film 133 may be obtained by performing a post-etching process to be described below.

The plurality of first wiring layers 135 may be disposed in first wiring holes 135H extending in the vertical direction (e.g., the Z direction) through the etch stop film 131 and the first insulating film 133, respectively. Accordingly, the plurality of first wiring layers 135 may extend in the vertical direction (e.g., the Z direction) through the etch stop film 131 and the first insulating film 133, respectively. Each of the plurality of first wiring layers 135 may have a first width d1 in a first horizontal direction (e.g., the X direction) parallel to the upper surface of the substrate 110. In an embodiment, the first width d1 may be in a range of about 12 nm to about 20 nm. For example, the first width d1 of the plurality of first wiring layers 135 may be about 15 nm. In an embodiment, the plurality of first wiring layers 135 may have a different first width from each other. For example, in an embodiment some of the plurality of first wiring layers 135 may have a first width of about 14 nm, and some other first wiring layers 135 may have a first width of about 15 nm. The plurality of first wiring layers 135 may be electrically connected to transistors included in the semiconductor device 100 through the first lower contact structure 123a connected to the plurality of first wiring layers 135.

In an embodiment, the first wiring layer 135 may overlap the plurality of first lower contact structures 123a in the vertical direction (e.g., the Z direction). However, embodiments of the present inventive concept are not necessarily limited thereto. For example, in an embodiment, some of the first wiring layers 135 may not overlap the plurality of first lower contact structures 123a in the vertical direction (e.g., the Z direction). In this embodiment, unlike an embodiment shown in FIG. 1, the entire area of the lower surface of the first wiring layer 135 that does not overlap with the first lower contact structure 123a in the vertical direction (e.g., the Z direction) is in direct contact with the interlayer insulating film 121 and some of the plurality of first lower contact structures 123a may be omitted.

In an embodiment, each of the plurality of first wiring layers 135 may include a first barrier layer 135a and a first metal layer 135b. The first barrier layer 135a may conformally cover the inner wall of the first wiring hole 135H. The first metal layer 135b may fill an empty space inside the first wiring hole 135H formed by inner walls of the first barrier layer 135a. In an embodiment, the metal material may include, for example, at least one compound selected from tungsten (W), copper (Cu), aluminum (Al), nickel (Ni), cobalt (Co), molybdenum (Mo), and an alloy thereof.

The plurality of second wiring layers 137 may be disposed in second wiring holes 137H extending in the vertical direction (e.g., the Z direction) through the etch stop film 131 and the first insulating film 133, respectively. Accordingly, the plurality of second wiring layers 137 may extend in the vertical direction (e.g., Z direction) through the etch stop film 131 and the first insulating film 133, respectively. Each of the plurality of second wiring layers 137 may have a second width d2 in the first horizontal direction (X direction). In an embodiment, the second width d2 may be in a range of about 15 nm to about 50 nm. For example, the second width d2 of the plurality of second wiring layers 137 may be about 19 nm. In an embodiment, the second width d2 may be greater than the first width d1 of the first wiring layer 135. In an embodiment, the plurality of second wiring layers 137 may have a different second width from each other. For example, in an embodiment some of the plurality of second wiring layers 137 may have a second width of about 19 nm, and some other second wiring layers 137 may have a second width of about 22 nm. In an embodiment, through the second lower contact structure 123b connected to the plurality of second wiring layers 137, a ground voltage or a source voltage for operating the semiconductor device 100 may be applied to the plurality of second wiring layers 137.

In an embodiment, the second wiring layer 137 may overlap the plurality of second lower contact structures 123b in the vertical direction (e.g., the Z direction). However, embodiments of the present inventive concept are not necessarily limited thereto. For example, in an embodiment, some of the second wiring layer 137 may not overlap with the plurality of second lower contact structures 123b in the vertical direction (e.g., Z direction). In this embodiment, unlike an embodiment shown in FIG. 1, the entire area of the lower surface of the second wiring layer 137 that does not overlap with the second lower contact structure 123b in the vertical direction (e.g., the Z direction) is in direct contact with the interlayer insulating film 121, and some of the plurality of second lower contact structures 123b may be omitted.

In an embodiment, each of the plurality of second wiring layers 137 may include a second barrier layer 137a and a second metal layer 137b. The second barrier layer 137a may conformally cover the inner wall of the second wiring hole 137H. The second metal layer 137b may fill an empty space inside the second wiring hole 137H formed by inner walls of the second barrier layer 137a. In an embodiment, the second barrier layer 137a and the second metal layer 137b may be formed of materials substantially the same as or similar to those of the first barrier layer 135a and the first metal layer 135b, respectively.

In an embodiment, the first wiring layer 135 and the second wiring layer 137 may be spaced apart from each other within the first insulating film 133. The arrangement of the first wiring layer 135 and the second wiring layer 137 shown in FIG. 1 is an example, and embodiments of the present inventive concept are not necessarily limited thereto. For example, in some embodiments the first wiring layer 135 and the second wiring layer 137 may be alternately arranged in the first horizontal direction (X direction).

In an embodiment, the surface of the second etch stop film 131b, the surface of the third etch stop film 131c, and the surface of the first insulating film 133 directly contacting the first wiring layer 135 may have a carbon concentration in a range of about 2.0 at % to about 3.0 at %. In an embodiment, the surface of the second etch stop film 131b, the surface of the third etch stop film 131c, and the surface of the first insulating film 133 directly contacting the second wiring layer 137 may have a carbon concentration in a range of about 2.0 at % to about 3.0 at %. For example, the surface of the etch stop film 131 and the first insulating film 133 in direct contact with the second wiring layer 137 may have a carbon concentration less than or equal to about 3 at %. The carbon concentration may be obtained by performing a post-etching process to be described below.

In an embodiment, the surface of the second etch stop film 131b, the surface of the third etch stop film 131c, and the surface of the first insulating film 133 directly contacting the first wiring layer 135 may have a fluorine concentration of about 25.0 at % to about 36.0 at %. In an embodiment, the surface of the second etch stop film 131b, the surface of the third etch stop film 131c, and the surface of the first insulating film 133 directly contacting the second wiring layer 137 may have a fluorine concentration of about 25.0 at % to about 36.0 at %. For example, the surface of the etch stop film 131 and the first insulating film 133 in direct contact with the first wiring layer 135 and the second wiring layer 137 may have a fluorine concentration less than or equal to about 36.0 at %. Like the carbon concentration described above, the fluorine concentration may be obtained by performing the post-etching process.

Compared to conventional wiring structures manufactured without performing a separate post-processing process after the etching process, the wiring structure 130 according to an embodiment manufactured by performing the post-etching process may have a relatively low carbon concentration and a relatively low fluorine concentration on the surface of the second etch stop film 131b, the surface of the third etch stop film 131c, and the surface of the first insulating film 133. Accordingly, the resistance of the first wiring layer 135 and the resistance of the second wiring layer 137 due to the carbon atoms and the fluorine atoms may be relatively reduced. Accordingly, resistive-capacitive (RC) delay of the semiconductor device 100 including the wiring structure 130 according to an embodiment may be reduced and functional characteristics may be increased.

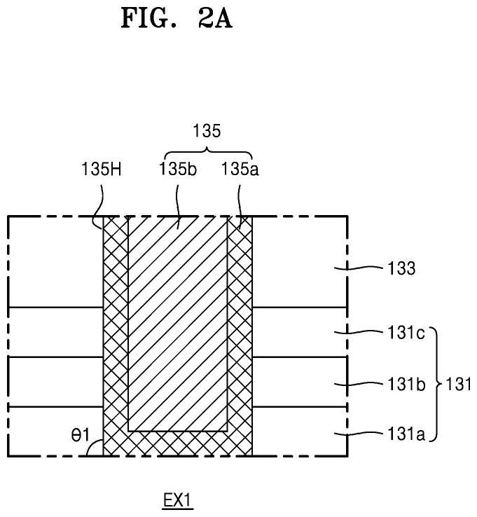

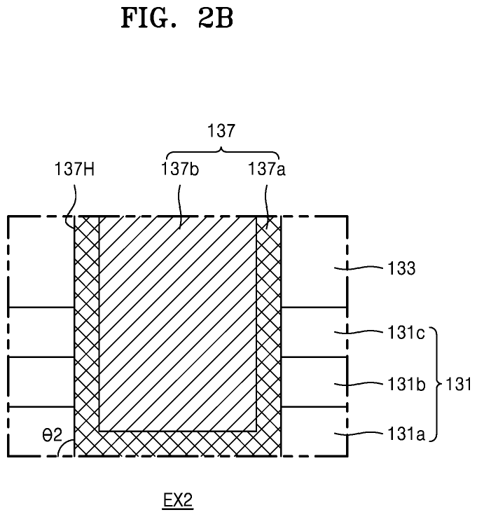

In an embodiment as shown in FIG. 1, the first wiring layer 135 and the second wiring layer 137 may have substantially vertical profiles in a cross-section parallel to the vertical direction (e.g., the Z direction) and the first horizontal direction (e.g., the X direction). For example, the sidewall of the first wiring layer 135 forms a first inclination angle 81 (see FIG. 2A) which is close to about 90 degrees with respect to the first horizontal direction (e.g., the X direction), and the sidewall of the second wiring layer 137 may form a second inclination angle θ2 (see FIG. 2B) which is close to about 90 degrees with respect to the first horizontal direction (e.g., the X direction). Hereinafter, the first wiring layer 135 and the second wiring layer 137 will be described in detail with reference to FIGS. 2A and 2B together.

FIG. 2A is an enlarged cross-sectional view of an area EX1 in FIG. 1. FIG. 2B is an enlarged cross-sectional view of an area EX2 of FIG. 1.

Referring to FIGS. 1, 2A, and 2B together, the sidewall of the first wiring layer 135 may form a first inclination angle θ1 with an imaginary line extending in the first horizontal direction (e.g., the X direction). In an embodiment, the first inclination angle θ1 may be in a range of about 88 degrees to about 90 degrees. The first inclination angle θ1 of the first wiring layer 135 may be obtained by adjusting the flow rate of etching gases in the etching process of the first insulating film 133 and the etching process of the second etch stop film 131b, as described below.

In an embodiment, a sidewall of the second wiring layer 137 may form a second inclination angle θ2 with an imaginary line extending in the first horizontal direction (e.g., the X direction). In an embodiment, the second inclination angle θ2 may be in a range of about 83 degrees to about 87 degrees. The second inclination angle θ2 of the second wiring layer 137 may be obtained by adjusting the flow rate of etching gases in the etching process of the first insulating film 133 and the etching process of the second etch stop film 131b, as described below. In a conventional wiring structure, a wiring layer included in the wiring structure has a tapered cross-sectional profile in which a horizontal width gradually decreases from an upper surface towards a lower surface. Accordingly, the lower surface of the wiring layer has a relatively narrow horizontal width, and as a result, the wiring layer is unloaded from the contact structure disposed on the lower surface of the wiring layer, such that there is poor connection between the wiring layer and the contact structure. On the other hand, in the wiring structure 130 according to an embodiment, the first wiring layer 135 included in the wiring structure 130 may have a first inclination angle θ1 close to about 90 degrees, and the second wiring layer 137 may have a second inclination angle θ2 close to about 90 degrees. Therefore, the first wiring layer 135 and the second wiring layer 137 have horizontal widths that are relatively constant with respect to the upper surface and the lower surface, such that unloading of the first wiring layer 135 and the second wiring layer 137 to the first lower contact structure 123a and the second lower contact structure 123b, respectively, may be prevented. Accordingly, a poor connection between the first wiring layer 135 and the first lower contact structure 123a and a poor connection between the second wiring layer 137 and the second lower contact structure 123b may be prevented, and furthermore, the functional reliability of the semiconductor device 100 including the wiring structure 130 may be increased.

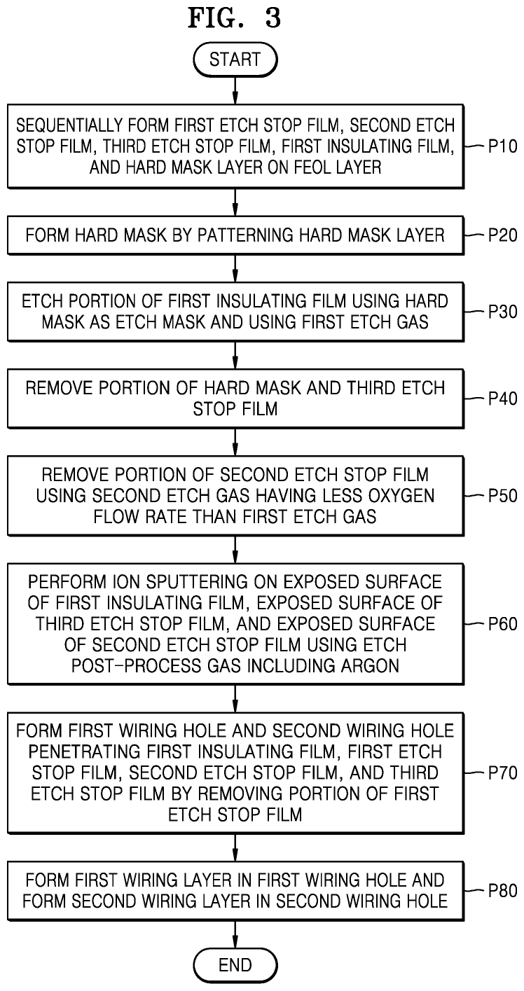

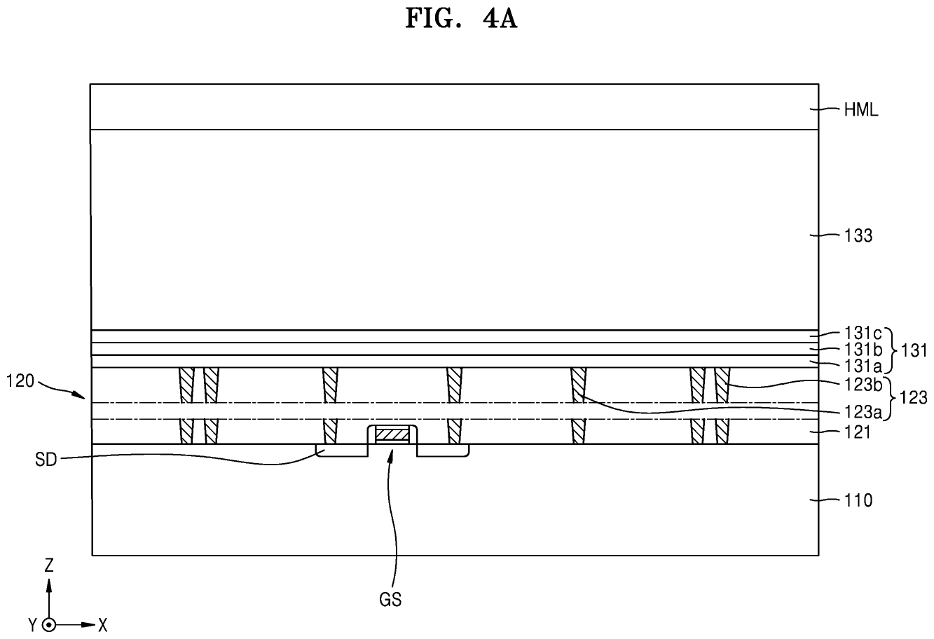

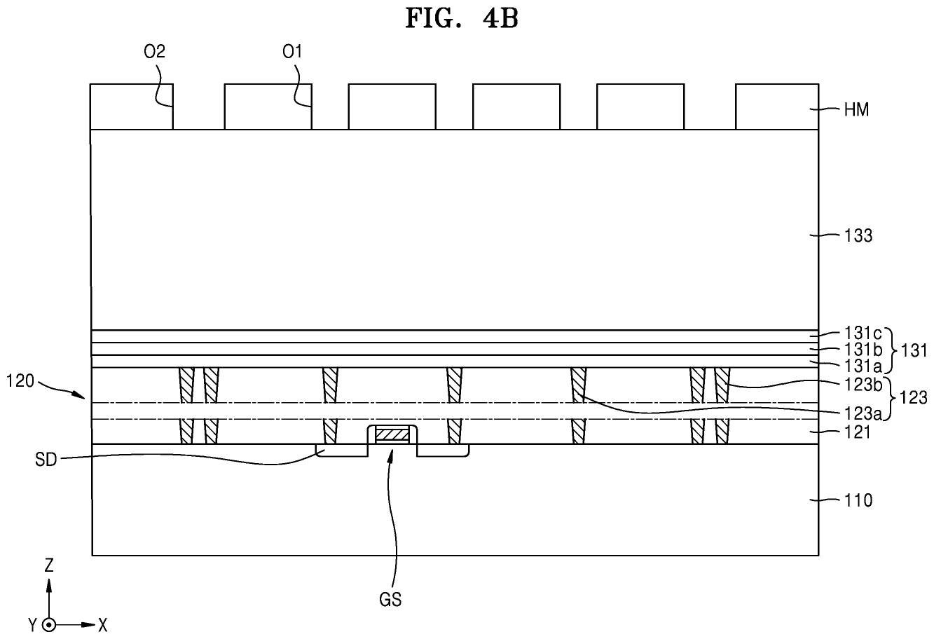

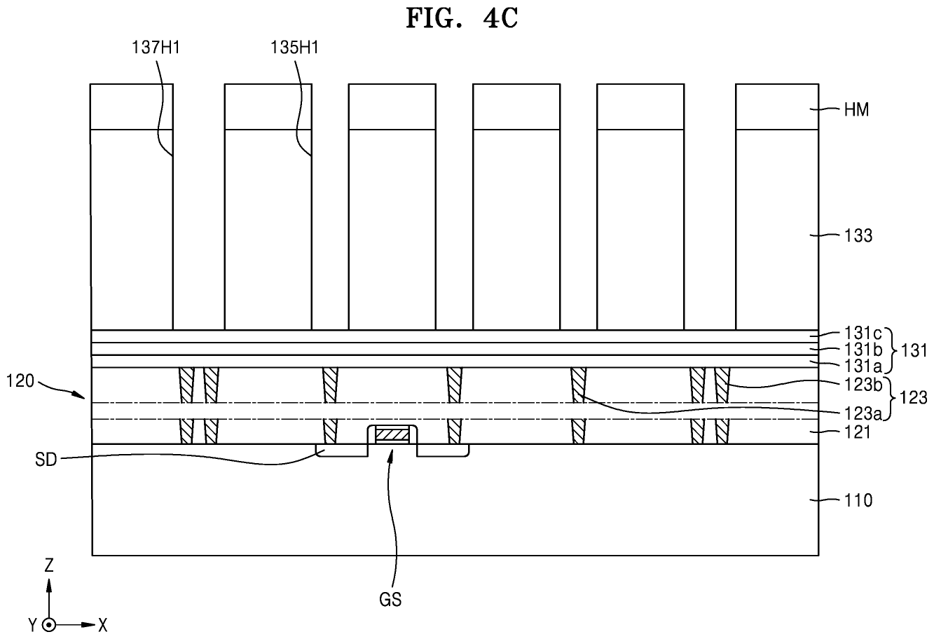

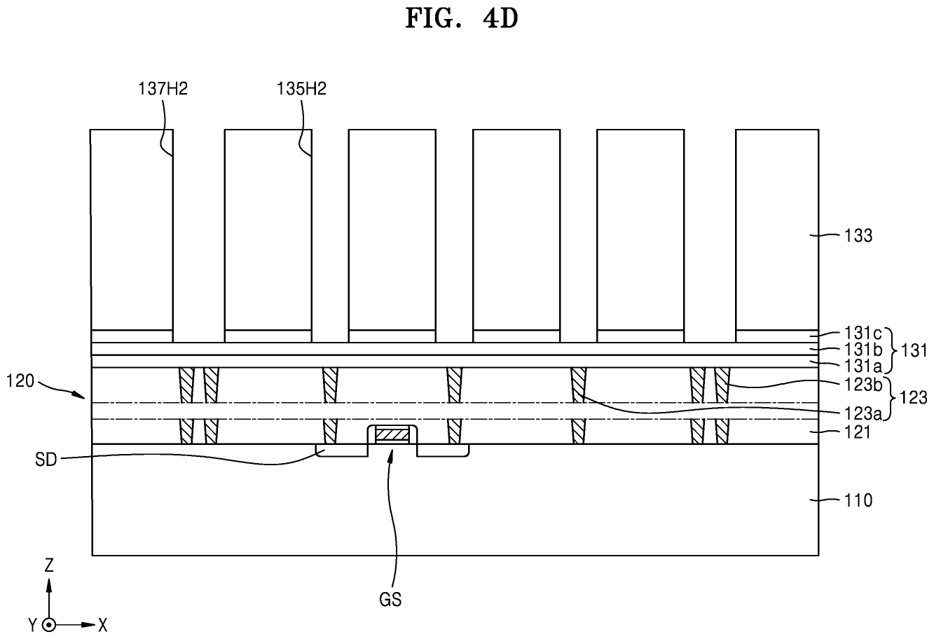

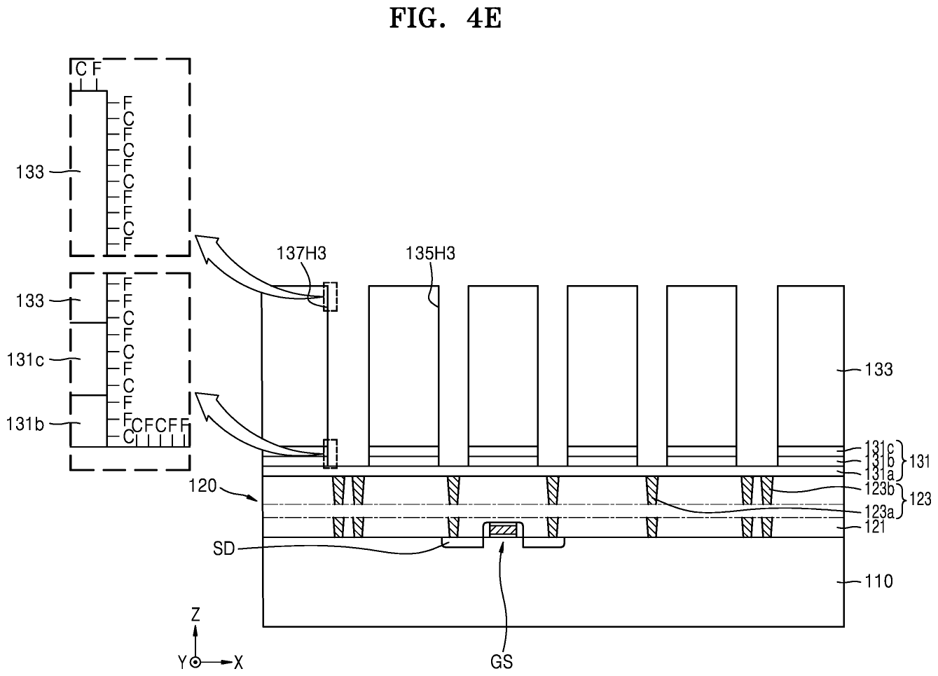

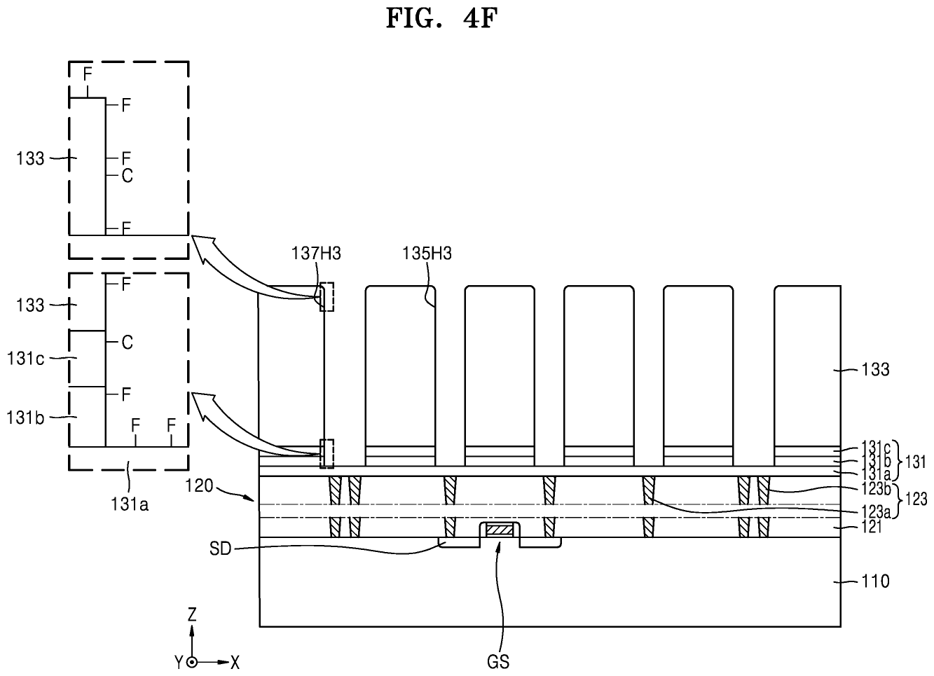

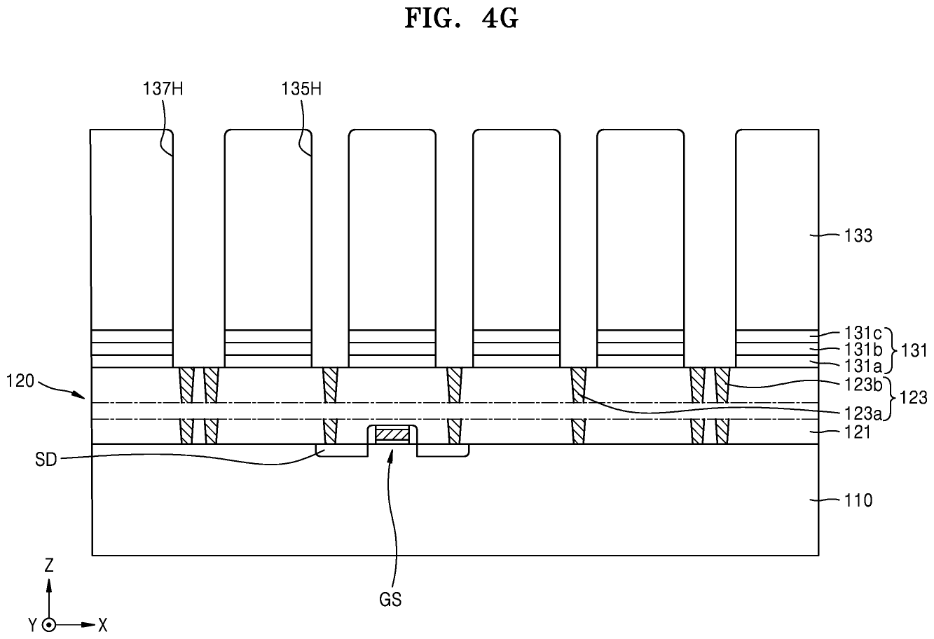

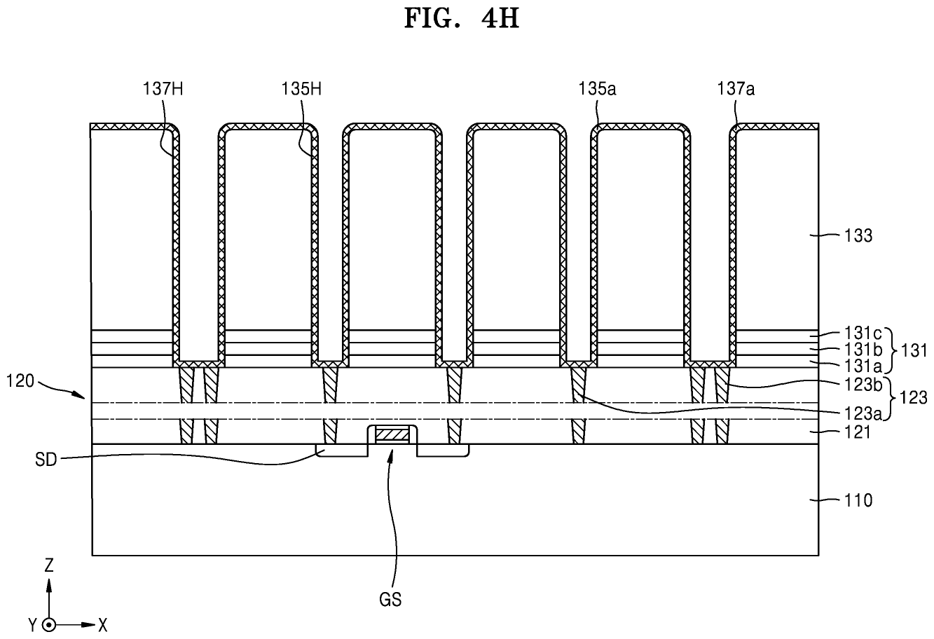

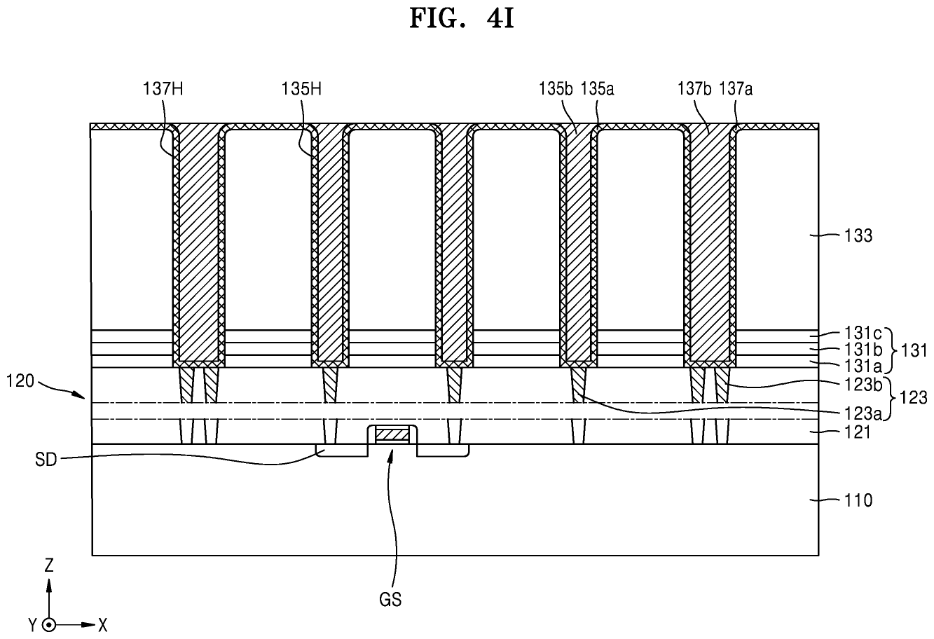

FIG. 3 is a flowchart illustrating a manufacturing process of the wiring structure 130 according to an embodiment. FIGS. 4A to 4I are cross-sectional views illustrating each step of a manufacturing process of the wiring structure 130 according to embodiments of the present inventive concept.

Referring to FIGS. 3 and 4A, first, the FEOL layer 120 disposed on the substrate 110 may be formed. In an embodiment, the FEOL layer 120 may be formed by a FEOL process. The FEOL process may include, for example, a planarization process, a cleaning process, a process of forming a hole, a process of forming a well, a process of forming a gate structure, and a process of forming a source/drain region. However, embodiments of the present inventive concept are not necessarily limited thereto. Next, a first etch stop film 131a, a second etch stop film 131b, a third etch stop film 131c, a first insulating film 133, and a hard mask layer HML may be sequentially formed on the FEOL layer 120 (e.g., in the Z direction) in block P10. In an embodiment, the first etch stop film 131a, the second etch stop film 131b, the third etch stop film 131c, the first insulating film 133, and the hard mask layer HML may be formed by performing any one process of Physical Vapor Deposition (PVD), Chemical Vapor Deposition (CVD), and Atomic Layer Deposition (ALD). However, embodiments of the present inventive concept are not necessarily limited thereto. In an embodiment, the first etch stop film 131a and the third etch stop film 131c may be made of aluminum oxide, and the second etch stop film 131b may be made of ODC. In an embodiment, the hard mask layer HML may be made of titanium nitride (TiN).

Referring to FIGS. 3 and 4B, in the resulting product of FIG. 4A, a hard mask HM may be formed by patterning a hard mask layer HML (see FIG. 4A) using a mask pattern in block P20. The hard mask HM may have a plurality of first openings O1 and a plurality of second openings O2. The plurality of first openings O1 may have a width substantially equal to or similar to the first width d1 of the first wiring layer 135 described with reference to FIGS. 1 and 2A, and the plurality of second openings O2 may have a width substantially equal to or similar to the second width d2 of the second wiring layer 137 described with reference to FIGS. 1 and 2A.

Referring to FIGS. 3 and 4C, in the resulting product of FIG. 4B, the first insulating film 133 may be etched using the hard mask HM as an etch mask in block P30. In block P30, portions of the first insulating film 133 exposed by the plurality of first openings O1 and the plurality of second openings O2 of the hard mask HM are etched, such that a first opening hole 135H1 and a second opening hole 137H1 may be formed through the first insulating film 133 exposed by the first openings O1 and the second openings O2, respectively, and extending in a vertical direction (Z direction). In an embodiment, the etching process may be performed using a first etching gas including nitrogen (N₂), oxygen (O₂), argon (Ar), and fluorocarbon. The fluorocarbon may be, for example, C₄F₈, CF₄, or a combination thereof. However, embodiments of the present inventive concept are not necessarily limited thereto. In an embodiment, the etching process may be a plasma etching process using the first etching gas. In an embodiment, a flow rate of the nitrogen included in the first etching gas may be in a range of about 10 sccm to about 400 sccm. In an embodiment, the flow rate of the oxygen included in the first etching gas may be in a range of about 5 sccm to about 25 sccm. In an embodiment, the flow rate of the argon included in the first etching gas may be in a range of about 200 sccm to about 1500 sccm. In an embodiment, the flow rate of the fluorocarbon included in the first etching gas may be in a range of about 20 sccm to about 1100 sccm.

In an embodiment, during the etching process, a DC voltage in a range of about 400 V to about 800 V may be applied to an upper electrode of a substrate processing apparatus for performing the etching process. When the DC voltage is applied to the upper electrode, the first opening hole 135H1 and the second opening hole 137H1 formed by the etching process may have a substantially vertical profile on a cross-section parallel to the vertical direction (e.g., the Z direction) and the first horizontal direction (e.g., the X direction).

Referring to FIGS. 3, 4D, and 4E, in the resulting product of FIG. 4C, the hard mask HM may be removed, and a portion of the third etch stop film 131c exposed by the first opening hole 135H1 and the second opening hole 137H1 may be removed in block P40. In an embodiment, the hard mask HM and the third etch stop film 131c may be removed through a strip process. However, embodiments of the present inventive concept are not necessarily limited thereto. In block P40, a portion of the third etch stop film 131c exposed by the first opening hole 135H1 and the second opening hole 137H1 is removed, such that a third opening hole 135H2 and a fourth opening hole 137H2 extending in the vertical direction (e.g., the Z direction) may be formed through the first insulating film 133 and the third etch stop film 131c exposed by the first opening hole 135H1 and the second opening hole 137H1, respectively.

Next, a portion of the second etch stop film 131b exposed by the third opening hole 135H2 and the fourth opening hole 137H2 may be etched using a second etching gas in block P50. In block P50, a portion of the second etch stop film 131b exposed by the first opening hole 135H2 and the second opening hole 137H2 is etched, such that a fifth opening hole 135H3 and a sixth opening hole 137H3 extending in the vertical direction (e.g., the Z direction) may be formed through the first insulating film 133, the third etch stop film 131c, and the second etch stop film 131b exposed by the first opening hole 135H2 and the second opening hole 137H2, respectively. In an embodiment, the second etching gas may include oxygen, nitrogen, and fluorocarbon. In an embodiment, the fluorocarbon may be, for example, C₄F₈. However, embodiments of the present inventive concept are not necessarily limited thereto. In an embodiment, a flow rate of the oxygen included in the second etching gas may be in a range of about 5 sccm to about 25 sccm. In an embodiment, a flow rate of the nitrogen included in the second etching gas may be in a range of about 0 sccm to about 150 sccm. In an embodiment, the flow rate of the fluorocarbon included in the second etching gas may be in a range of about 5 sccm to about 60 sccm. In an embodiment, the flow rate of oxygen included in the second etching gas used in block P40 may be greater than the flow rate of oxygen included in the first etching gas used in block P30. For example, the flow rate of oxygen included in the second etching gas may be about 20 sccm, and the flow rate of oxygen included in the first etching gas may be about 10 sccm. By increasing the flow rate of oxygen included in the second etching gas than the first etching gas, the fifth opening hole 135H3 and the sixth opening hole 137H3 may have substantially vertical profiles in a cross-section parallel to the vertical direction (e.g., the Z direction) and the first horizontal direction (e.g., the X direction).

Referring to FIGS. 3 and 4F, in the resulting product of FIG. 4E, a post-etching process may be performed on the inner wall of the fifth opening hole 135H3 and the inner wall of the sixth opening hole 137H3 in block P60. In an embodiment, the post-etching process may be an ion sputtering process using post-etching gas. In an embodiment, the post-etching treatment gas may include argon. In an embodiment, the post-etching gas may further include nitrogen, hydrogen (H₂), and N₂CO. In an embodiment, the concentration of the argon gas included in the post-etching gas may be in a range of about 200 sccm to about 2000 sccm. As the post-etching process is performed, the upper regions of both sidewalls of the first insulating film 133 penetrated by the fifth opening hole 135H3 and the sixth opening hole 137H may be recessed by ions generated using the post-etching gas. Accordingly, in an embodiment, an upper region of the sidewall of the first insulating film 133 (e.g., an upper region adjacent to the first wiring layer 135 and second wiring layer 137) may have a rounded shape. By performing a post-etching process using a post-etching gas including argon gas, carbon atoms and fluorine atoms on the surface of the first insulating film 133, the surface of the third etch stop film 131c, and the surface of the second etch stop film 131b exposed by the fifth opening hole 135H3 and the sixth opening hole 137H3 may be removed. Accordingly, the surface of the first insulating film 133, the surface of the third etch stop film 131c, and the surface of the second etch stop film 131b may have a relatively low carbon concentration and a relatively low fluorine concentration compared to conventional wiring structures.

Referring to FIGS. 3 and 4G, in the resulting product of FIG. 4F, a portion of the first etch stop film 131a exposed by the fifth opening hole 135H3 and the sixth opening hole 137H3 may be removed in block P70. In an embodiment, the portion of the first etch stop film 131a may be removed by a strip process. However, embodiments of the present inventive concept are not necessarily limited thereto. In block P70, portions of the first etch stop film 131a exposed by the fifth opening hole 135H3 and the sixth opening hole 137H3 are removed, such that a first wiring hole 135H and a second wiring hole 137H penetrating the first insulating film 133, the third etch stop film 131c, the second etch stop film 131b, and the first etch stop film 131a may be formed in the portions of the first etch stop film 131a exposed by the fifth opening hole 135H3 and the sixth opening hole 137H3, respectively. In an embodiment, the first wiring holes 135H and the second wiring holes 137H may have substantially vertical profiles in a cross-section parallel to the vertical direction (e.g., the Z direction) and the first horizontal direction (e.g., the X direction). For example, the sidewall of the first wiring layer 135 may have a first inclination angle θ1 (see FIG. 2A) close to about 90 degrees with respect to the first horizontal direction (X direction), and the sidewall of the second wiring layer 137 may have a second inclination angle θ2 (see FIG. 2B) close to about 90 degrees with respect to the first horizontal direction (X direction). The first inclination angle θ1 and the second inclination angle θ2 may be obtained by adjusting the flow rate of etching gases in the etching process of the first insulating film 133 and the etching process of the second etch stop film 131b describe above.

Referring to FIGS. 3, 4H, and 4I, in the resulting product of FIG. 4G, a first barrier layer 135a and a second barrier layer 137a may be formed on the inner walls of the first wiring hole 135H and the inner wall of the second wiring hole 137H, respectively, in block P80. Next, a first metal layer 135b filling an empty space of a first wiring hole 135H on which a first barrier layer 135a is formed on the inner wall of the first wiring hole 135H and a second metal layer 137b filling the empty space of the second wiring hole 137H on which the second barrier layer 137a is formed on the inner wall of the second wiring hole 137H may be formed in block P80. In an embodiment, the first metal layer 135b and the second metal layer 137b may be formed through an electroplating process. However, embodiments of the present inventive concept are not necessarily limited thereto.

Next, referring to FIG. 3, a planarization process may be performed on the result of FIG. 4i in block P90. In an embodiment, the planarization process may be a chemical mechanical polishing (CMP) process. However, embodiments of the present inventive concept are not necessarily limited thereto. Through the planarization process, the first barrier layer 135a, the second barrier layer 137a, the first metal layer 135b, and the second metal layer 137b may be planarized, such that the upper surface of the first barrier layer 135a, the upper surface of the second barrier layer 137a, the upper surface of the first metal layer 135b, and the upper surface of the second metal layer 137b are at substantially the same vertical level as the upper surface of the first insulating film 133. The wiring structure 130 shown in FIG. 1 may be manufactured by performing block P90 on the resulting product of FIG. 4i.

The wiring structure 130 according to an embodiment manufactured by performing the post-etching process may have a relatively low carbon concentration and a relatively low fluorine concentration on the surface of the second etch stop film 131b, the surface of the third etch stop film 131c, and the surface of the first insulating film 133. Accordingly, the resistance of the first wiring layer 135 and the resistance of the second wiring layer 137 due to the carbon atoms and the fluorine atoms may be relatively reduced. Accordingly, the RC delay of the semiconductor device 100 including the wiring structure 130 according to an embodiment may be reduced and functional characteristics may be increased.

Furthermore, in the wiring structure 130 according to an embodiment, the first wiring layer 135 included in the wiring structure 130 may have a first inclination angle θ1 close to about 90 degrees, and the second wiring layer 137 may have a second inclination angle θ2 close to about 90 degrees. Therefore, the first wiring layer 135 and the second wiring layer 137 have horizontal widths that are relatively constant with respect to the upper surface and the lower surface, such that unloading of the first wiring layer 135 and the second wiring layer 137 to the first lower contact structure 123a and the second lower contact structure 123b, respectively, may be prevented. Accordingly, a poor connection between the first wiring layer 135 and the first lower contact structure 123a and a poor connection between the second wiring layer 137 and the second lower contact structure 123b may be prevented, and furthermore, the functional reliability of the semiconductor device 100 including the wiring structure 130 may be increased.

While the present inventive concept has been particularly shown and described with reference to embodiments thereof, it will be understood that various changes in form and details may be made therein without departing from the spirit and scope of the following claims.

What is claimed is:

1. A wiring structure comprising:
an etch stop film disposed on a substrate;
a first insulating film disposed on the etch stop film; and
a first wiring layer extending in a vertical direction perpendicular to an upper surface of the substrate and extending through the first insulating film and the etch stop film,
wherein a sidewall of the first wiring layer forms a first inclination angle of about 88 degrees to about 90 degrees with respect to a first horizontal direction parallel to the upper surface of the substrate, and a surface of the first insulating film and a surface of the etch stop film in direct contact with the first wiring layer have a carbon (C) concentration less than or equal to about 3 at %.

2. The wiring structure of claim 1, wherein the first wiring layer has a first width in a range of about 12 nm to about 20 nm in the first horizontal direction.

3. The wiring structure of claim 1, wherein a surface of the first insulating film and a surface of the etch stop film in direct contact with the first wiring layer have a fluorine (F) concentration less than or equal to about 36 at %.

4. The wiring structure of claim 1, further comprising a second wiring layer spaced apart from the first wiring layer and extending in the vertical direction through the first insulating film and the etch stop film.

5. The wiring structure of claim 4, wherein the second wiring layer has a second width in a range of about 15 nm to about 50 nm in the first horizontal direction.

6. The wiring structure of claim 4, wherein a sidewall of the second wiring layer forms a second inclination angle in a range of about 83 degrees to about 87 degrees with respect to the first horizontal direction.

7. The wiring structure of claim 4, wherein a surface of the first insulating film and a surface of the etch stop film in direct contact with the second wiring layer have a C concentration less than or equal to about 3 at %.

8. The wiring structure of claim 4, wherein a surface of the first insulating film and a surface of the etch stop film in direct contact with the second wiring layer have a F concentration less than or equal to about 36 at %.

9. The wiring structure of claim 1, wherein the etch stop film comprises oxide-doped carbide (ODC).

10. The wiring structure of claim 1, wherein an upper region of the first insulating film adjacent to the first wiring layer has a rounded shape.

11. A semiconductor device comprising:
a substrate;
a front end of line (FEOL) layer including a plurality of lower contact structures including a first lower contact structure and a second lower contact structure, and an interlayer insulating film covering the plurality of lower contact structures; and
a wiring structure disposed on the FEOL layer,
wherein the wiring structure comprises an etch stop film disposed on the substrate, a first insulating film disposed on the etch stop film, and a first wiring layer extending in a vertical direction perpendicular to an upper surface of the substrate and extending through the first insulating film and the etch stop film,
wherein a sidewall of the first wiring layer forms a first inclination angle of about 88 degrees to about 90 degrees with respect to a first horizontal direction parallel to an upper surface of the substrate and a surface of the first insulating film and a surface of the etch stop film in direct contact with the first wiring layer have a carbon (C) concentration of about 3 at % or less.

12. The semiconductor device of claim 11, wherein the first wiring layer has a first width in a range of about 12 nm to about 20 nm in the first horizontal direction.

13. The semiconductor device of claim 11, wherein a surface of the first insulating film and a surface of the etch stop film in direct contact with the first wiring layer have a fluorine (F) concentration less than or equal to about 36 at %.

14. The semiconductor device of claim 11, wherein the first lower contact structure overlaps the first wiring layer in the vertical direction.

15. The semiconductor device of claim 11, further comprising:
a second wiring layer spaced apart from the first wiring layer and extending in the vertical direction through the first insulating film and the etch stop film,
wherein a sidewall of the second wiring layer forms a second inclination angle in a range of about 83 degrees to about 87 degrees with respect to the first horizontal direction, and the second wiring layer has a second width in the first horizontal direction in a range of about 15 nm to about 50 nm.

16. The semiconductor device of claim 15, wherein a surface of the first insulating film and a surface of the etch stop film in direct contact with the second wiring layer have a C concentration less than or equal to about 3 at % and a F concentration less than or equal to about 36 at %.

17. The semiconductor device of claim 15, wherein the second lower contact structure overlaps the second wiring layer in the vertical direction.

18. The semiconductor device of claim 15, wherein an upper region adjacent to the first wiring layer and an upper region adjacent to the second wiring layer of the first insulating film have a rounded shape.

19. A wiring structure comprising:
an etch stop film disposed on a substrate and including oxide-doped carbide (ODC);
a first insulating film disposed on the etch stop film;
a first wiring layer extending in a vertical direction perpendicular to an upper surface of the substrate and extending through the first insulating film and the etch stop film; and
a second wiring layer spaced apart from the first wiring layer and extending in the vertical direction through the first insulating film and the etch stop film,
wherein a sidewall of the first wiring layer forms a first inclination angle in a range of about 88 degrees to about 90 degrees with respect to a first horizontal direction parallel to a top surface of the substrate, a sidewall of the second wiring layer forms a second inclination angle in a range of about 83 degrees to about 87 degrees with respect to the first horizontal direction, and a surface of the first insulating film in direct contact with the first wiring layer, a surface of the etch stop film and a surface of the first insulating film in direct contact with the second wiring layer, and a surface of the etch stop film have a carbon (C) concentration less than or equal to about 3 at %.

20. The wiring structure of claim 19, wherein the first wiring layer has a first width in a range of about 12 nm to about 20 nm in the first horizontal direction and the second wiring layer has a second width in a range of about 15 nm to about 50 nm in the first horizontal direction, and the first width is less than the second width.
